(19) United States
(12) Patent Application Publication
(10) Pub. No.: US 2024/0120242 A1
(43) Pub. Date: Apr. 11, 2024

(54) Process Control Monitor Device Structure for Buried TSV Formation in IC Wafers

(71) Applicant: Raytheon Company, Waltham, MA (US)

(72) Inventors: Sean P. Kilcoyne, Lompoc, CA (US); Eric R. Miller, Orcutt, CA (US)

(21) Appl. No.: 17/963,937

(22) Filed: Oct. 11, 2022

(51) Int. Cl. H01L 21/66; H01L 21/768; H01L 23/48

(52) U.S. Cl. CPC H01L 22/34; H01L 21/76898; H01L 22/14; H01L 23/481

(57) ABSTRACT

An integrated circuit wafer is produced to include a substrate comprising a conductive layer and an insulating layer. The wafer can further be produced to include one or more circuit TSVs formed at least partially through the substrate and associated with an integrated circuit (IC). A test structure configured to facilitate testing of the integrity of the one or more circuit TSVs can be formed on the wafer. The test structure can include a first test TSV formed one of partially through the insulating layer, or through the insulating layer and partially through the conductive layer of the substrate, and a second test TSV formed one of partially through the insulating layer, or through the insulating layer and partially through the conductive layer of the substrate. The first test TSV and the second test TSV can operate as witness TSVs to the operability of the circuit TSVs.

### BACKGROUND

Through-silicon vias (TSVs) are commonly formed in silicon wafers and/or dies during the production of integrated circuits (ICs), typically during backend processing, to allow access to the backside of the wafer circuitry. In processes utilizing SOI (silicon-on-insulator) wafers, the TSVs are formed through the bottom side of the active device structure and protrude through the active silicon and buried oxide and terminate in the silicon handle substrate. In other words, buried beneath the active circuitry during production of the silicon wafers or dies. The handle wafer substrate protects the TSVs and other delicate circuit components from damage and contamination until a user of the silicon wafer or die receives the product from the manufacturer. Upon receiving the silicon wafer, the user may then perform one or more processes on the silicon wafer to remove the handle substrate and expose the TSVs.

In certain situations, and depending on desired uses, the substrate (e.g., handle wafer) may be retained on the silicon wafer to provide continued protection and may only be removed by the purchaser after other processes have been performed on the silicon wafer to prepare the wafer for use. For example, a silicon wafer may undergo a bonding process such as direct bonding with another silicon wafer prior to having the substrate (e.g., handle wafer) removed and prior to performing chemical/mechanical polishing to expose the buried TSVs.

Manufacturing processes used to make silicon wafers may not be entirely reliable and TSVs may not be formed to an adequate depth in the silicon wafer to ensure proper operability of the TSVs. Because bonding and other processes may be done on silicon wafers before exposing the buried TSVs, silicon wafers may be changed such that they are not returnable to the manufacturer once the user is able to confirm whether the buried TSVs have been formed to an adequate depth for proper operation. Accordingly, a user may incur great losses in time, materials, processing, and cost before discovering that TSVs of a certain silicon wafer are improperly formed and, therefore, inoperable. To avoid such losses, it is desirable for a user to determine operability of TSVs before performing any further processes on a purchased silicon wafer.

### BRIEF DESCRIPTION OF THE DRAWINGS

Features and advantages of the present technology will be apparent from the detailed description which follows, taken in conjunction with the accompanying drawings, which together illustrate, by way of example, features of the present technology; and, wherein:

FIG. 1 illustrates a top view of an integrated circuit wafer.

FIG. 2 illustrates a cross-sectional view of an integrated circuit of the integrated circuit wafer of FIG. 1.

FIG. 3 illustrates a cross-sectional view of an integrated circuit wafer and a zoomed in view of a single integrated circuit of the integrated circuit wafer of FIG. 1.

FIG. 4 illustrates a cross-sectional view of an integrated circuit wafer and a zoomed in view of a single integrated circuit of the integrated circuit wafer of FIG. 1 after removal of a layer of a substrate (e.g., handle wafer).

FIG. 5 illustrates a top view of an integrated circuit wafer according to an example of the present disclosure.

FIG. 6 illustrates a zoomed-in view of the integrated circuit wafer of FIG. 5 showing die locations and dicing streets.

FIG. 7a illustrates an improperly formed TSV on an exemplary integrated circuit wafer.

FIG. 7b illustrates a properly formed TSV on an exemplary integrated circuit wafer.

FIG. 8a illustrates an improperly formed TSV on an exemplary integrated circuit wafer.

FIG. 8b illustrates the improperly formed TSV of FIG. 8a with a layer of the substrate removed.

FIG. 8c illustrates a properly formed TSV on an exemplary integrated circuit wafer.

FIG. 8d illustrates the properly formed TSV of FIG. 8c with a layer of the substrate removed to expose a conductive surface of the TSV.

FIG. 9 illustrates an exemplary process of forming an exemplary circuit TSV on an integrated circuit wafer according to at least one example of the disclosure.

FIG. 10 illustrates an exemplary process of forming an exemplary test TSV on an integrated circuit wafer according to at least one example of the disclosure.

FIG. 11a illustrates an exemplary process of testing a test structure according to at least one example of the present disclosure.

FIG. 11b illustrates an exemplary circuit diagram of the test structure of FIG. 11a.

FIG. 12a illustrates an exemplary process of testing a test structure according to at least one example of the present disclosure.

FIG. 12b illustrates an exemplary circuit diagram of the test structure of FIG. 12a.

FIG. 13 illustrates an array of TSVs formed in a wafer as a test structure according to at least one example of the present disclosure.

FIG. 14 illustrates an array of TSVs formed in a wafer as a test structure according to at least one example of the present disclosure.

FIG. 15 illustrates a method of configuring an integrated circuit wafer according to at least one example of the present disclosure.

Reference will now be made to the exemplary embodiments illustrated, and specific language will be used herein to describe the same. It will nevertheless be understood that no limitation of the scope of the present technology is thereby intended.

### DETAILED DESCRIPTION

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness can in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, “adjacent” refers to the proximity of two structures or elements. Particularly, elements that are identified as being “adjacent” can be either abutting or connected. Such elements can also be near or close to each other without necessarily contacting each other. The exact degree of proximity can in some cases depend on the specific context.

An initial overview of the inventive concepts are provided below and then specific examples are described in further detail later. This initial summary is intended to aid readers in understanding the examples more quickly, but is not intended to identify key features or essential features of the examples, nor is it intended to limit the scope of the claimed subject matter.

Disclosed herein is a test structure configured to facilitate testing of the integrity of one or more circuit TSVs associated with an integrated circuit (IC), the circuit TSVs being formed at least partially through a substrate (e.g., handle wafer) comprising an insulating layer and a conductive layer. The test structure device can include a first test TSV formed one of partially through the insulating layer, or through the insulating layer and partially through the conductive layer of the substrate and a second test TSV formed one of (1) partially through the insulating layer, or (2) through the insulating layer and partially through the conductive layer of the substrate. The first test TSV and the second test TSV can act as witness TSVs to operability of the circuit TSVs.

Further disclosed herein is an integrated circuit wafer. The integrated circuit wafer can include a substrate (e.g., handle wafer) comprising a conductive layer and an insulating layer. The integrated circuit wafer can further include one or more circuit TSVs formed at least partially through the substrate and associated with an integrated circuit (IC). The integrated circuit wafer can further include a test structure configured to facilitate testing of the integrity of the one or more circuit TSVs. The test structure can include a first test TSV formed one of (1) partially through the insulating layer, or (2) through the insulating layer and partially through the conductive layer of the substrate, and a second test TSV formed one of partially through the insulating layer, or through the insulating layer and partially through the conductive layer of the substrate. The first test TSV and the second test TSV can act as witness TSVs to the operability of the circuit TSVs.

Further disclosed herein is a method of configuring an integrated circuit wafer. The method can include providing a substrate (e.g., handle wafer) comprising a conductive layer and an insulating layer. The method can further include forming a plurality of holes one of partially through the insulating layer, or through the insulating layer and partially through the conductive layer of the substrate. The plurality of holes can comprise at least one or more circuit holes associated with an integrated circuit (IC). The plurality of holes can further include a first test hole and a second hole of a test structure, the test structure being configured to facilitate testing of the integrity of one or more circuit TSVs formed using the one or more circuit holes. The method can further include lining, at least partially, the substrate within the plurality of holes with an electrically insulating material. The method can further include removing a portion of the electrically insulating material to expose a portion of the substrate within the first test hole and the second test hole. The method can further include filling the plurality of holes with a conductive material to respectively form a plurality of TSVs, comprising one or more circuit TSVs, the first test TSV, and the second test TSV, from the one or more circuit holes, the first test hole, and the second test hole. The first and second test TSVs can act as witness TSVs to the operability of the circuit TSVs.

Further disclosed herein is a method of testing an integrated circuit wafer as described herein. The method can include electrically connecting the first test TSV to the second test TSV using an electrical probe and measuring an electrical property (e.g., an electrical resistance or an electrical conductance) between the first test TSV and the second test TSV through the conductive layer to determine the integrity of the first and second test TSVs, and to witness the integrity of the circuit TSVs. The method can further include establishing that the circuit TSVs are inoperable when an electrical property measured between the first and second test TSVs is outside of a predetermined value range, and establishing that the circuit TSVs are operable when at least one electrical property measured between the first and second test TSVs is within the predetermined value range.

To further describe the present technology, examples are now provided with reference to the figures. In electronics, integrated circuits (ICs) are often formed on a silicon wafer (sometimes referred to as a slice or substrate). A wafer is a thin slice of a semiconductor material used for the fabrication of ICs. The wafer serves as the substrate for microelectronic devices built in and upon the wafer to form the various ICs. The wafer typically undergoes any number of microfabrication processes, such as doping, ion implantation, etching, thin-film deposition of various materials, and photolithographic patterning, in order to form the ICs. Finally, once the individual microcircuits are formed on the wafer, the wafer can be separated into individual ICs by wafer dicing, after which, the separate ICs can be used for a variety of intended purposes.

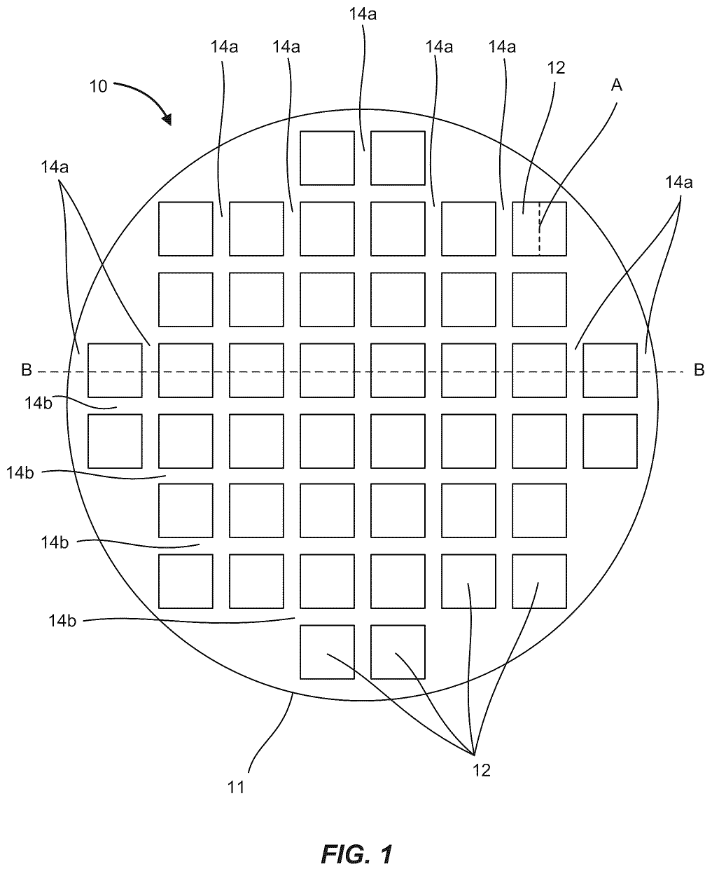

To illustrate the problem solved by the principles described herein, a brief overview of a silicon wafer with integrated circuits formed thereon will be described with respect to FIG. 1. As illustrated in FIG. 1, a wafer 10 can be provided. The wafer 10 can be made of a semiconductor material for forming ICs. The wafer 10 can include a substrate 11 which can include one or more layers, including one or more insulating layers and one or more conductive layers. As shown, a plurality of ICs 12 can be manufactured on the substrate 11. Although only a few of the ICs 12 are indicated in the drawing, it is to be understood that each square on the substrate 11 represents an individual IC 12 formed on the substrate 11. While illustrated as squares, it will be appreciated that individual ICs can have any shape. The shapes of the ICs are not intended to be limited by this disclosure in any way.

Once ICs 12 are formed on the substrate 11, the wafer 10 may be diced or cut along one or more dicing streets to separate the ICs 12 from other ICs 12 on the wafer 10 into separate dies with each die comprising one or more ICs. The cutting or dicing separates the ICs 12 from unused wafer material or unused substrate 11. As shown, the areas outside of the ICs 12 can be dicing streets 14. For example, the wafer 10 can include a plurality of vertical dicing streets 14a and a plurality of horizontal dicing streets 14b. Although all of the possible dicing streets may not be indicated in FIG. 1, it is to be appreciated that any area between the ICs 12 on the wafer 10 can be cut away and used as a dicing street 14.

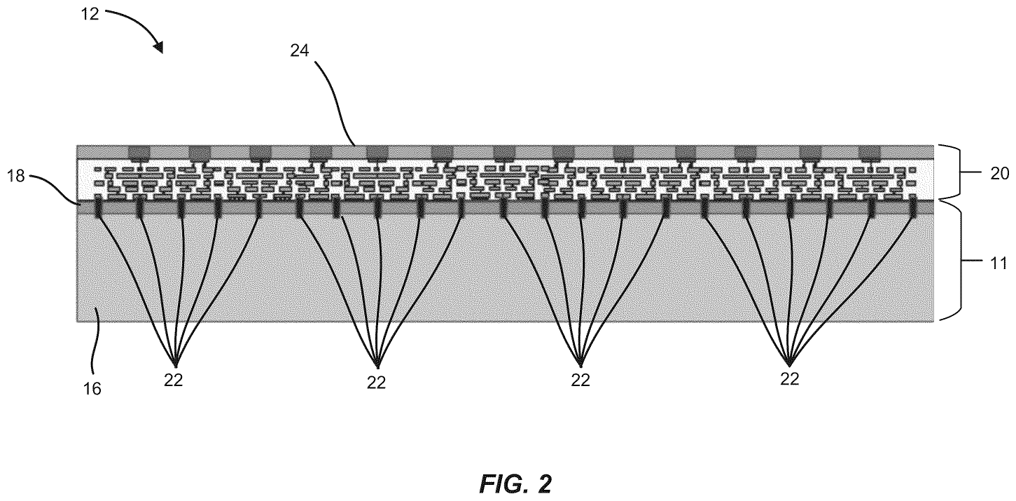

Individual ICs 12 formed on the substrate 11 can be configured as shown in the cross-sectional view shown in FIG. 2. The cross-section of IC 12 shown in FIG. 2 is taken along line A shown in FIG. 1. The IC 12 of FIG. 2 can include the wafer (i.e., substrate) 10. The substrate 11 can include multiple layers including a cover layer 16 and a TSV layer 18. The IC 12 can further include a circuit layer 20 including various circuits and circuit elements formed on the substrate 11 as part of the IC 12. To facilitate electrical communication between the IC 12 and a circuit board or other electronic component to which the IC 12 may be attached, one or more through-silicon vias (TSVs) 22 can be formed at least partially through the TSV layer 18 (typically made of silicon dioxide, for example) and the cover layer 16 (e.g., a silicon substrate sometimes referred to as a handle wafer). The TSVs 22 formed through the substrate 11 and associated with an IC 12 to provide electrical communication to the TSVs 22 can be referred to herein as “circuit TSVs.” As illustrated in FIG. 2, the circuit TSVs 22 can be buried beneath a portion of the substrate 11 such as the cover layer 16 and can also be buried beneath the circuit layer 20. Therefore, the circuit TSVs can be sandwiched between the circuit layer 20 and the cover layer 16 such that the circuit TSVs 22 are inaccessible without material removal being performed on the wafer.

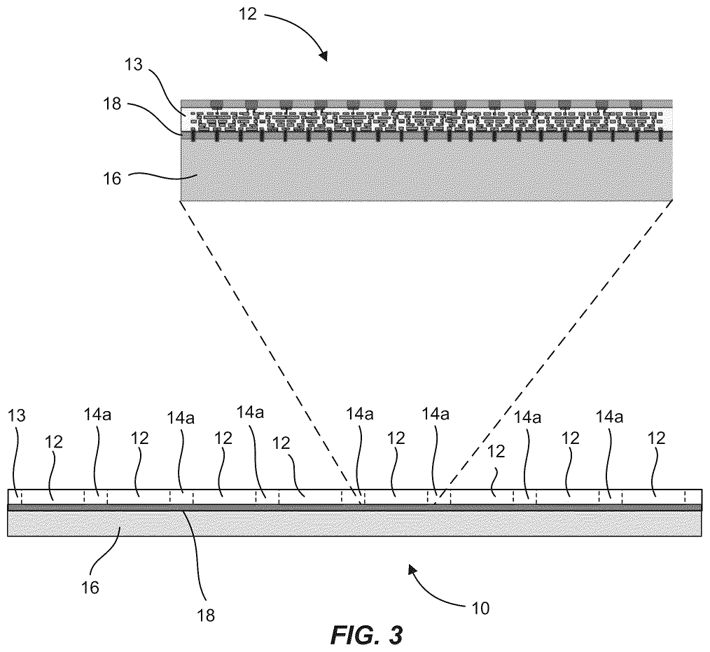

FIG. 3 illustrates a cross-sectional view of the wafer 10 taken along line BB shown in FIG. 1. The illustrated configuration in FIG. 3 shows the wafer 10 with a plurality of ICs 12 disposed thereon in an upper layer 13 of the wafer 10. FIG. 3 further illustrates a zoomed-in view of an individual IC 12 of the wafer 10. The wafer 10 and IC 12 of FIG. 3 are shown in a possible configuration in which the wafer 10 could be delivered by a manufacturer. Specifically, the cover layer 16 is in place over the TSVs 22 such that the TSVs 22 are “buried.” In the configuration shown in FIG. 3, the cover layer 16 covers and protects the TSVs 22 until such time that a user or manufacturer is ready to expose the TSVs for use.

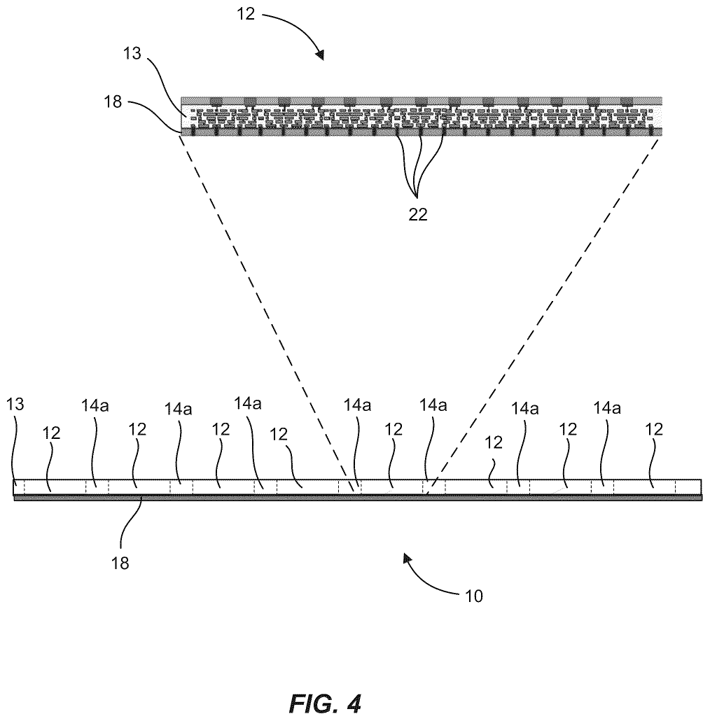

The cover layer 16 (e.g., silicon substrate sometimes referred to as a handle wafer) can be removed from the wafer 10 and ICs 12 by any chemical, mechanical, or other known process for material removal from a circuit wafer. The TSVs 22 can further be exposed by any known suitable process such as chemical mechanical polishing (CMP). The process of material removal and TSV exposure is not intended to be limited by this disclosure in any way. FIG. 4 illustrates the wafer 10 and IC 12 after the cover layer 16 has been removed. As shown in the zoomed-in view of IC 12, the TSVs 22 are exposed at a surface of the wafer 10 by the removal of cover layer 16.

Certain additional processes can be carried out on the wafer 10 prior to, or after, the removal of the cover layer 16. For example, an IC 12 can be fixed or bonded, at surface 24, to another IC 12 or circuit board configured to receive the IC 12. Also, a wafer 10 can be fixed or bonded, at surface 24, to another wafer 10. To maintain protection of the TSVs 22 it can be desirable to leave the cover layer 16 intact while performing additional processing, such as bonding, on the wafer 10. Accordingly, a problem may exist that a purchaser may perform processing and bonding on a very expensive wafer 10 that changes the wafer 10 and makes the wafer 10 unreturnable to a manufacturer should a manufacturing default exist in the wafer 10. For example, a manufacturer defect may exist in that the TSVs were not adequately formed a sufficient distance (e.g., formed to a short etch depth during via formation) through the substrate 11 to be properly exposed upon removal of the cover layer 16. However, the depth and formation of the TSVs cannot be discovered until the cover layer 16 is removed, exposing the TSVs. Therefore, the user can incur significant cost in purchasing and processing a wafer 10 before discovering that the wafer was improperly manufactured and unfit for use. Such processed wafers with manufacturing defects end up fit only to be discarded, thus wasting materials, time, money, and processing energy of the user. Therefore, it would be advantageous for a user/purchaser of wafers 10 to be able to determine the operability of the TSVs 22 before performing additional processing on the wafer 10. This disclosure describes principles for achieving the goal of determining operability of the TSVs 22 in a wafer 10 upon receipt by the user, without the need of additional processing to reveal the TSVs 22 first.

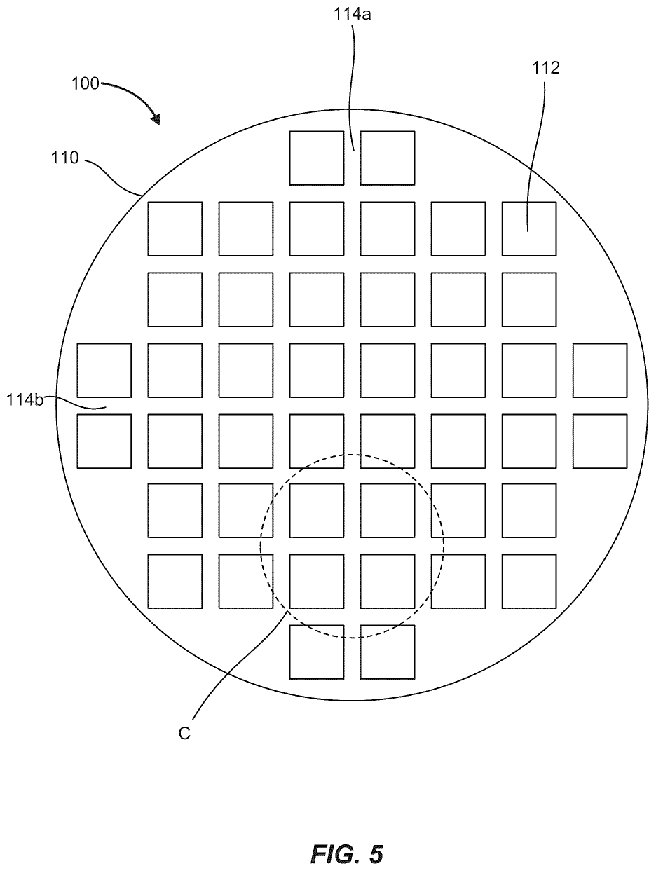

An exemplary wafer 100 including a test structure according to the technology described herein is described with respect to FIG. 5. As shown in FIG. 5, a wafer 100 can be provided, which can be similar is some respects to the wafer 10 described above and shown in FIGS. 1-4. The wafer 100 can be made of a semiconductor material for forming ICs 112. The wafer 100 can include a substrate 110 which can include one or more layers, including one or more insulating layers and one or more conductive layers. As shown, a plurality of ICs 112 can be manufactured on the substrate 110. Although only a few of the ICs 112 are indicated in the drawing, it is to be understood that each square on the substrate 110 represents an individual IC 112 formed on the substrate 110.

Once ICs 112 are formed on the substrate 110, the wafer 100 may be diced or cut along one or more dicing streets 114 to separate one or more ICs 112 from one or more other ICs 112 on the wafer 100 into separate dies with each die comprising one or more ICs 112, in this example case each die comprising a single IC 112. The cutting or dicing separates the ICs 112 from unused wafer material or unused substrate 110. As shown, the areas outside of the ICs 112 can be dicing streets 114. For example, the wafer 100 can include a plurality of vertical dicing streets 114a and a plurality of horizontal dicing streets 114b. Although all of the possible dicing streets may not be indicated in FIG. 1, it is to be appreciated that any area between the ICs 112 on the wafer 100 can be cut away and used as a dicing street 114.

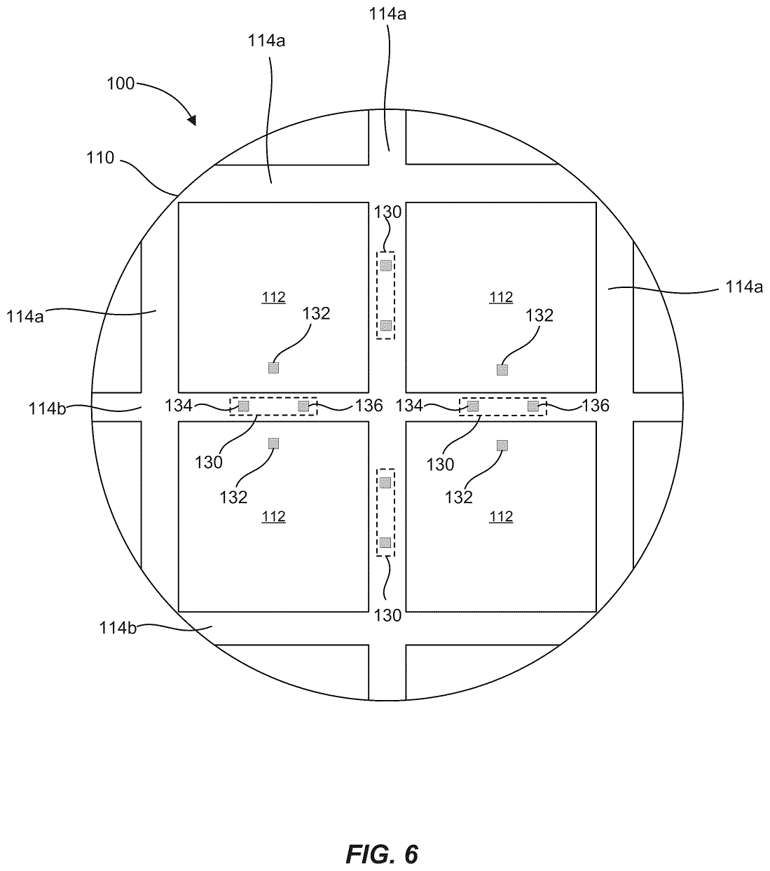

An enlarged view of region C of the wafer 100 is illustrated in FIG. 6 showing exemplary test structures 130 according to the principles of this disclosure. As shown in FIG. 6, the wafer 100 can include one or more test structures 130 configured to facilitate the testing of integrity of one or more circuit TSVs 132 associated with one or more integrated circuit ICs 112, the circuit TSVs 132 being formed at least partially through a substrate 110. Although each IC 112 in FIG. 6 is shown to include only one circuit TSV 132, this is for illustration purposes only. Those skilled in the art will appreciate that each IC 112 can include any number of circuit TSVs 132 necessary for operation of the integrated circuit 112. For example, each IC 112 can include a plurality circuit TSVs (e.g., such as is shown in FIG. 2 with TSVs 22) which each operate to provide electrical communication to and from the IC 112.

The test structure(s) 130 can each include a first test TSV 134 formed at least partially through the substrate 110 and a second test TSV 136 formed at least partially through the substrate 110. A test structure 130 or test TSV can be formed in one or more of the dicing streets 114, including a horizontal dicing street 114b, a vertical dicing street 114a, and/or at an intersection between a horizontal dicing street 114b and a vertical dicing street 114a. Any number of test structures 130 can be formed in the dicing streets 114 of the wafer 100. It will be appreciated that the test structures 130 and associated test TSVs 134, 136 illustrated in the figures are not necessarily drawn to scale. Further any of the test TSVs, the circuit TSVs, or any combination of these, can be formed to have any suitable cross-sectional configuration and shape and are not intended to be limited to those shown.

The first test TSV 134 and the second test TSV 136 can act as “witness” TSVs to the circuit TSVs 132. As used herein, the term “witness” or “witness TSV(s)” refers to one or more test TSVs 134, 136 that are interrogated (i.e., tested) for the purpose of determining the probable integrity (i.e., the operability (or lack of operability (i.e., inoperability)) for an intended purpose) of one or more circuit TSVs 132 when the operability/inoperability of the circuit TSV 132 cannot be directly tested and its integrity determined. In other words, the witness TSVs (e.g., the first test TSV 134 and/or the second test TSV 136) interrogated and confirmed to be formed properly for the desired operability can indicate, with some degree of probability based on etch uniformity, that the circuit TSV(s) 132 in proximity to, and/or formed at the same or similar time and/or with the same or similar process, as the witness TSVs are also likely operable. Conversely, the witness TSVs (e.g., the first test TSV 134 and/or the second test TSV 136) interrogated and confirmed to be formed improperly and therefore inoperable for the intended purpose can indicate that the circuit TSV(s) 132 in proximity to, and/or formed at the same or similar time and/or with the same or similar process, as the witness TSVs are also likely inoperable. Accordingly, the witness TSVs act as a witness to the operability of the circuit TSVs 132, thereby obviating the need to directly test operability of the circuit TSVs 132.

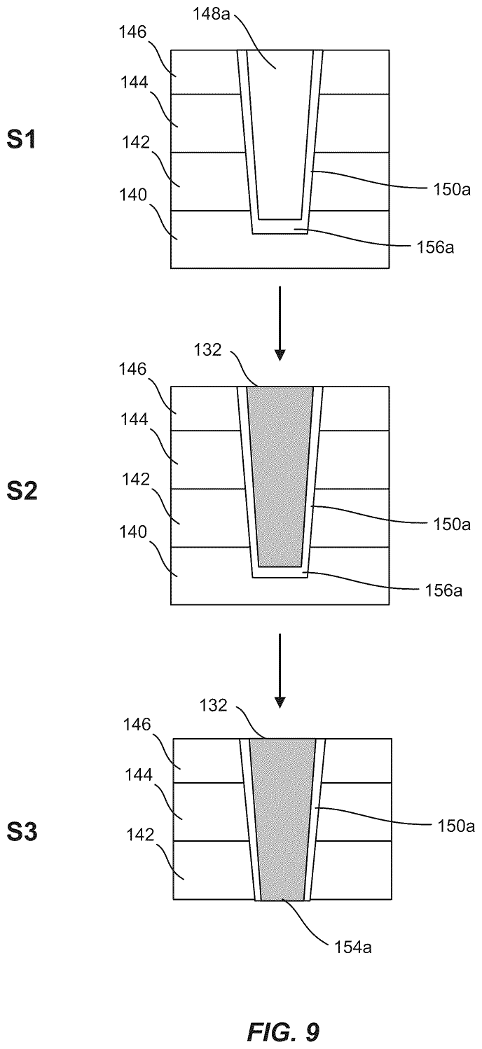

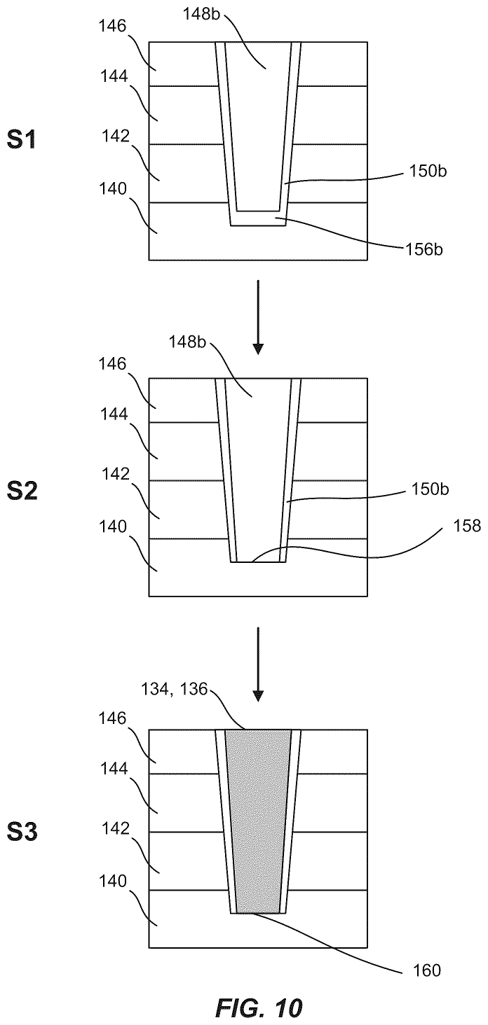

To act as witness TSVs, the first test TSV 134 and the second test TSV 136 can be formed at or close to the same time as the circuit TSVs 132. Additionally, or alternatively, the first test TSV 134 and the second test TSV 136 can be formed in the substrate 110 of the wafer 100 using the same, or at least a portion of the same, process used to form the circuit TSVs 132 in the substrate 110 of the wafer 100. The test TSVs 134 and 136 can be formed using the same or similar processes used to form circuit TSVs 132 (e.g., etching the via, lining the via with oxide, filling the via with tungsten, and using chemical mechanical polishing (CMP) to planarize the structure as shown in FIG. 9). However, the test TSVs 134 and 136 can include an added step during formation compared to the circuit TSVs 132 (e.g., etching the bottom of the liner to modify the test TSVs 134 and 136 to enable contact between the tungsten and the doped handle wafer (conductive layer 140) as shown in FIG. 10). To best ensure that the witness TSVs properly witness the integrity, namely the operability or inoperability, of the circuit TSVs 132, the witness TSVs can be formed at the same time and using the same process as used to form the circuit TSVs 132, therefore ensuring that the witness TSVs and the circuit TSVs 132 are formed to nearly the same specifications, including, but not limited to, from the same material(s), with the same or similar configurations, and so as to have the same depth through the substrate 110. Such a process can increase the likelihood that the circuit TSVs 132 and the witness TSVs will be formed to have the same operability or inoperability. However, it will be appreciated that it is not strictly necessary that witness TSVs be formed at the same time or with the same process as the circuit TSVs 132. Subtle variations in the timing and the processes used to form the circuit TSVs 132 and the witness TSVs will not necessarily adversely affect the ability of the witness TSVs to act as witnesses to the operability/inoperability of the circuit TSVs 132.

Furthermore, any number of test structures 130, each with one or more associated test TSVs 134, 136, can be formed in the dicing streets 114 of the wafer 100. It may be advantageous to add more test structures 130 because those test structures 130 (including the test TSVs 134 and 136) that are closer to the circuit TSVs 132 whose integrity is being determined are likely more reliable as witnesses to the circuit TSVs 132 than test structures 130 that are farther away from the circuit TSVs 132. Accordingly, any desired number of test structures can be formed in the dicing streets 114 of the wafer 100, and any single test structure 130, or a combination of test structures 130, can be systematically interrogated to determine the integrity of any given circuit TSV 132, or number of circuit TSVs 132. Indeed, it is likely that the probability that a circuit TSV 132 in question will have the same integrity as that of an interrogated test TSV will increase the closer the test TSV is to the circuit TSV in question. It will further be appreciated that the test structures 130 can also be placed in areas that are not the dicing streets. For example, test TSVs 134 and 136 can be formed in areas of an IC that are not covered by circuitry, thereby allowing access to the test TSVs. Alternatively, a designated dummy or test circuit (e.g., one of the ICs 112 shown in FIG. 6), or a designated blank space, can be formed in place of an IC 112 where test TSVs are disposed to allow for the test TSVs to be formed outside of the dicing streets 114.

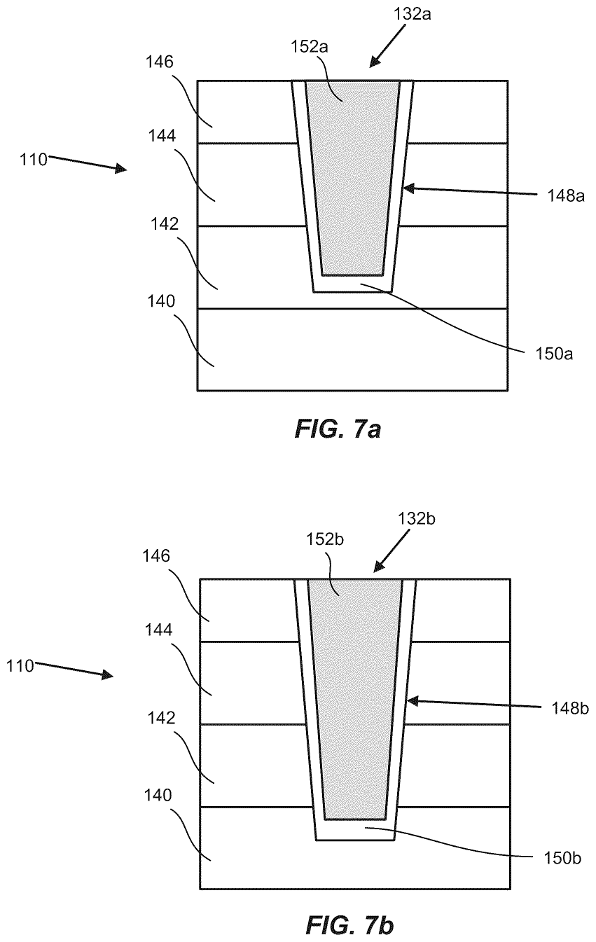

The formation, including proper and improper formation, of the TSVs (including circuit TSVs 132, first test TSV 134, and/or second test TSV 136) is illustrated and discussed with reference to FIGS. 7a and 7b. FIG. 7a illustrates a cross-sectional view of an exemplary TSV (can be representative of either a circuit TSV or a test TSV) formed at least partially through the substrate 110. It is to be understood that the exemplary TSV can be any of the TSVs formed through the substrate 110. However, for purposes of this example, the exemplary TSV will be referred to as a circuit TSV 132a. The circuit TSV 132a illustrated in FIG. 7a is improperly formed, as explained below. As illustrated in FIG. 7a, the substrate 110 can include one or more layers (e.g., 140, 142, 144, and 146). The layers are not necessarily drawn to scale in the figures. Each of the layers can have different electrically conductive properties and can be made of different materials. In the example shown, the layer 140 (e.g., conductive doped silicon layer or substrate) can comprise a conductive layer made of an electrically conductive material, such as doped silicon, or other similar conductive substrates. The conductive layer 140 is analogous to the cover layer 16 of FIG. 2, used to cover the TSVs of an IC. In other words, the conductive layer 140 can be removed using material removal processes to expose buried TSVs once the IC is ready for use. The layer 142 formed on the conductive layer 140 can comprise an insulating layer made of an insulating material, such as silicon dioxide. The layer 144 formed on the insulating layer 142 can comprise a conductive layer 144 made of a conductive material, such as silicon. The layer 146 formed on the conductive layer 144 can comprise another insulating layer 146, or interlayer dielectric, made of an insulating or dielectric material, such as an oxide.

The circuit TSV 132a can be formed through one or more layers of the substrate 110. The circuit TSV 132a can be disposed in a circuit TSV hole 148a defined through one or more layers of the substrate 110 by a material removal process, such as etching. The circuit TSV 132a can be at least partially insulated from one or more layers of the substrate 110 by at least partially lining the substrate 110 within the circuit TSV hole 148a with a lining 150a comprising an electrically insulating material, such as silicon oxide. Although the exemplary TSV is a circuit TSV 132a, it will be appreciated that the first test TSV 134 and the second test TSV 136 can be formed in the same way to at least partially insulate the first test TSV 134 and the second test TSV 136 from the substrate 110. For example, similar to the circuit TSV 132a, the first test TSV 134 and the second test TSV 136 can be at least partially lined with a lining 150a comprising an electrically insulating material, such as silicon oxide, to at least partially insulate the first test TSV 134 and the second test TSV 136 from one or more layers of the substrate 110. To provide conductance capability for each of the TSVs, the lined circuit TSV holes of each TSV can be filled with a conductive material 152a, such as tungsten.

To ensure proper operability of the circuit TSV 132a, or any TSV, the TSV should be formed at least through layers 142, 144, and 146 and at least partially through the conductive layer 140. The circuit TSV 132a should be formed to a depth that allows the conductive material 152a to reach at least to the conductive layer 140. As used herein, the term “partially through” when referring to forming a hole or TSV through a specified layer is intended to mean that the hole or TSV reaches the layer sufficiently to allow the conductive material 152a to reach at least the surface of the specified layer, no matter the degree or length of penetration into the specified layer. In other words, even if little to no actual penetration into the specified layer is accomplished, if the conductive material, TSV, or hole reaches a surface of the specified layer, it can be said that the hole, conductive material, or TSV is formed “partially through” the specified layer.

In such a configuration, when the conductive layer 140 is removed by material removal and/or subject to chemical mechanical polishing, the conductive material 152a should be exposed, ensuring proper electrical communication through the circuit TSV 132a to the IC. However, as illustrated in FIG. 7a, the TSV 132a is shown as being improperly formed as it does not extend through the layer 142 to reach the conductive layer 140. Therefore, the circuit TSV 132a will not be operable after removal of the conductive layer.

In contrast, FIG. 7b illustrates a cross-section of a properly formed circuit TSV 132b. As shown, the circuit TSV 132b is formed in circuit TSV hole 148b, lined with lining 150b, and filled with conductive material 152b. The circuit TSV 132b is formed through all of layers 142, 144, 146, and extends into the conductive layer 140, thereby ensuring operability of the circuit TSV 132b when the conductive layer 140 is removed.

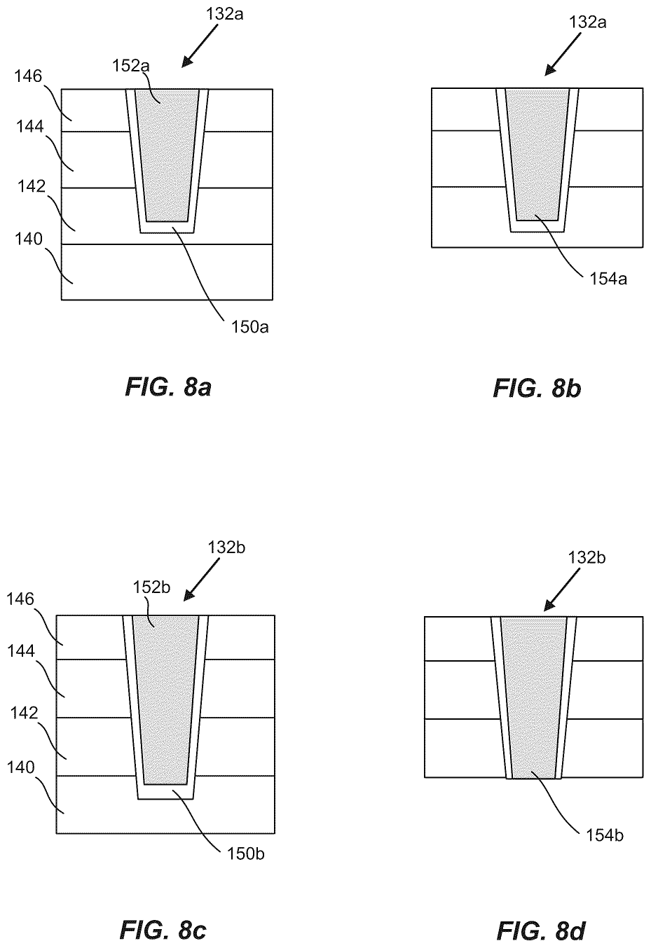

The operability and inoperability of the circuit TSVs 132a and 132b are illustrated with reference to FIGS. 8a, 8b, 8c, and 8d. As illustrated in FIG. 8a, the circuit TSV 132a is improperly formed and does not extend to the conductive layer 140. An end 154a of the circuit TSV 132a is meant to make electrical contact with other elements and facilitate electrical communication between the IC and other elements. However, as shown in FIG. 8b, the end 154a of the circuit TSV 132a remains buried within the layer 142 after the removal and polishing of conductive layer 140. Therefore, the circuit TSV 132a is not exposed by the removing of conductive layer 140, and is therefore inoperable. In other words, the circuit TSV 132a cannot make contact with any other elements and cannot facilitate electrical communication through the circuit TSV 132a. In a case where this can only be discovered after performing certain processing on a wafer containing such a TSV, at least one IC on the wafer, and possibly the whole wafer, may be unusable and may need to be scrapped.

In contrast, as illustrated in FIG. 8c, the circuit TSV 132b is properly formed and extends to the conductive layer 140. Therefore, as shown in FIG. 8d, an end 154b of the circuit TSV 132b is exposed at the bottom after removal and polishing of conductive layer 140. Therefore, the circuit TSV 132b is operable. In other words, the circuit TSV 132b can make contact with other elements and can facilitate electrical communication through the circuit TSV 132b. However, in a case where this can only be discovered after performing certain processing on a wafer containing such a TSV, a user will not know whether an IC and a wafer is useable until after performing the processing on the wafer.

The test TSVs (i.e., first test TSV 134 and second test TSV 136) can serve to remedy such problems by facilitating quasi-testing (not direct testing, but testing via one or more proxy or witness TSVs) of the circuit TSVs 132 before any processing or irreparable material removal is done to any parts of the wafer 100 containing the TSVs. In other words, one or more test TSVs can act as witness TSVs to indicate the likely operability of one or more circuit TSVs 132 through interrogating the test TSVs to determine their integrity (i.e., operability). In one example, to facilitate interrogation and testing of the test TSVs 134, 136, the test TSVs 134, 136 can be formed in accessible areas of the wafer 100 and can be configured to be conductive with other portions of the wafer 100 before the conductive layer 140 is removed. This can be accomplished by forming the test TSVs 134, 136 with a slightly different process than the circuit TSVs 132. For example, one such process for forming the circuit TSVs 132 is illustrated in FIG. 9. As shown, a circuit TSV hole 148a can be formed in the substrate by any suitable material removal process and the circuit TSV hole 148a can be lined with an insulating lining 150a. This portion of the process is illustrated in S1 of FIG. 9. The circuit TSV hole 148a can be filled with a conductive material to form the circuit TSV 132. As shown in S2 of FIG. 9, a bottom 156a of the lining 150a can be caused to remain as the circuit TSV hole 148a is filled with the conductive material. Accordingly, the conductive material of the circuit TSV 132 is insulated from the conductive layer 140 of the substrate 110. The conductive portion of the conductive material is not exposed in the circuit TSV 132 until the conductive layer 140 is removed and the lining 150a is removed to expose the conductive end 154a of the circuit TSV 132, as shown in S3 of FIG. 9.

Conversely, an example process for forming the test TSVs 134 and 136 is illustrated in FIG. 10. As shown, a test TSV hole 148b can be formed in the substrate by any suitable material removal process (e.g., dry etching or gas etching) and the test TSV hole 148b can be lined with an insulating lining 150b. This portion of the process is illustrated in S1 of FIG. 10, which is similar to S1 of FIG. 9. However, in contrast to the process of FIG. 9, before the test TSV hole 148b is filled with a conductive material to form a test TSV (e.g., one or more of test TSVs 134, 136), an etching process can be carried out to remove a bottom portion 156b of the lining 150b in order to expose a portion 158 of the conductive layer 140 of the substrate 110, as shown in S2 of FIG. 10. In one example, the etching process can be carried out by a highly selective dry etching process in which a plasma is energetically focused on the bottom of the test TSV hole 148b to specifically etch out the insulating lining 150b material at the bottom, while leaving the insulating lining material intact or in place on the sides of the hole 148b. In S3 of FIG. 10, the test TSV hole 148b can be filled with a conductive material, such as tungsten, to form the test TSV (e.g., the test TSVs 134, 136). Accordingly, the conductive material of the test TSVs 134, 136 is caused to be in electrical communication with the conductive layer 140 of the substrate 110. Accordingly, the lining 150b in the test TSVs 134, 136 is at least partially open at a portion (in this example, portion 158 of conductive layer 140) of the test TSVs 134, 136. With the test TSVs 134, 136 of the test structure 130 configured as described above with reference to FIG. 10, the test TSVs 134, 136, if formed to a proper depth in the substrate 110, will be in electrical communication with the conductive layer 140 of the substrate 110. Furthermore, with the bottom etched out before filing the test TSV holes 148b, and with the first and second test TSVs 134, 136 formed to a depth sufficient to reach the conductive layer 140, the first test TSV 134 and the second test TSV 136 will be in electrical communication with each other through the conductive layer 140. However, even with the bottom etched out before filing the test TSV holes 148b of the first test TSV 134 and the second test TSV 136, if the first and second test TSVs 134 and 136 are not formed to a depth sufficient to reach the conductive layer 140, then the first test TSV 134 and the second test TSV 136 will not be in electrical communication with each other through the conductive layer 140.

Having been formed with similar processes or at the same time as the circuit TSVs 132, the first test TSV 134 and the second test TSV 136 will likely be formed to the same or similar depth within the substrate 110 to the circuit TSVs 132. Accordingly, the depth of the first test TSV 134 and the second test TSV 136 will be indicative of, and witness, the depths of the circuit TSVs 132. In other words, if an electrical property (at least one of an electrical conduction or an electrical resistance) measured between the first test TSV 134 and the second test TSV 136 through the conductive layer 140 (e.g., doped silicon substrate) is within a predetermined value range, then the test TSVs 134 and 136 are formed to a sufficient depth within the substrate 110. With the test TSVs 134 and 136 formed to a sufficient depth within the substrate 110, it is likely that the circuit TSVs 132 are also formed to a sufficient depth to be operable.

However, if an electrical property (at least one of an electrical conduction or an electrical resistance) measured between the first test TSV 134 and the second test TSV 136 through the conductive layer 140 (e.g., doped silicon substrate) is outside a predetermined value range, then the test TSVs 134 and 136 are not formed to a sufficient depth or not properly formed within the substrate 110. With the test TSVs 134 and 136 not being formed properly or to a sufficient depth within the substrate 110, it is likely that the circuit TSVs 132 are also not formed properly or to a sufficient depth to be operable, therefore indicating that the circuit TSVs 132 are inoperable. In other words, the test TSVs 134 and 136 act as witnesses to the depths, operability, and/or inoperability of the circuit TSVs 132.

It is to be appreciated that no specific limitation as to a range of predetermined values measured between test TSVs 134 and 136 is intended by this disclosure. As many different applications may have different desired levels of electrical conductance, resistance, or other electrical properties, it is not the intention of this disclosure to limit the range of what would be an acceptable value measured for an electrical property between test TSVs 134 and 136. Such ranges may be determined by those skilled in the art who may be using the test structures as described herein depending on to which applications or circuits the test structures are applied.

To provide an example, it is understood that if no electrical conductance is measured between test TSVs 134 and 136, then there is no electrical connection between the test TSVs 134 and 136, indicating that the test TSVs, and therefore circuit TSVs 132, are inoperable. Therefore, it can be said that an electrical conduction of zero is outside of the predetermined value range of conductance because at least some level of conductance is desired between the test TSVs 134 and 136 for the IC to be operable. Similarly, if substantially infinite electrical resistance is measured between test TSVs 134 and 136, then there is also little to no electrical connection between the test TSVs 134 and 136, indicating that the test TSVs, and therefore circuit TSVs 132, are inoperable. Therefore, it can be said that an electrical resistance substantially equal to infinity is outside of the predetermined value range for resistance because a lower level of resistance is desired to allow conductance between the test TSVs 134 and 136 for the IC to be operable.

As another example, for a certain application, a user may desire a resistance of 1 ohm or less when testing the operability of a TSV for a specific intended purpose. In this case, if the resistance measured between TSVs 134 and 136 to be 1 ohm or less, it can be said that the TSVs 134 and 136 are operable, and therefore the circuit TSVs 132 are witnessed to be operable as well. However, if the resistance is measured to be outside of the 1 ohm or less range (e.g., greater than 1 ohm), the TSVs 134 and 136 are inoperable for their intended purpose, and therefore the circuit TSVs 132 are witnessed to be inoperable as well. Similarly, for a certain application, a user may desire a conductance of 1 S or greater when testing the operability of a TSV for a specific intended purpose. In this case, if the conductance measured between TSVs 134 and 136 is 1 S or greater, it can be said that the TSVs 134 and 136 are operable, and therefore the circuit TSVs 132 are witnessed to be operable as well. However, if the conductance is measured to be outside of the 1 S or greater range (e.g., less than 1 S), the TSVs 134 and 136 are inoperable for their intended purpose, and therefore the circuit TSVs 132 are witnessed to be inoperable as well.

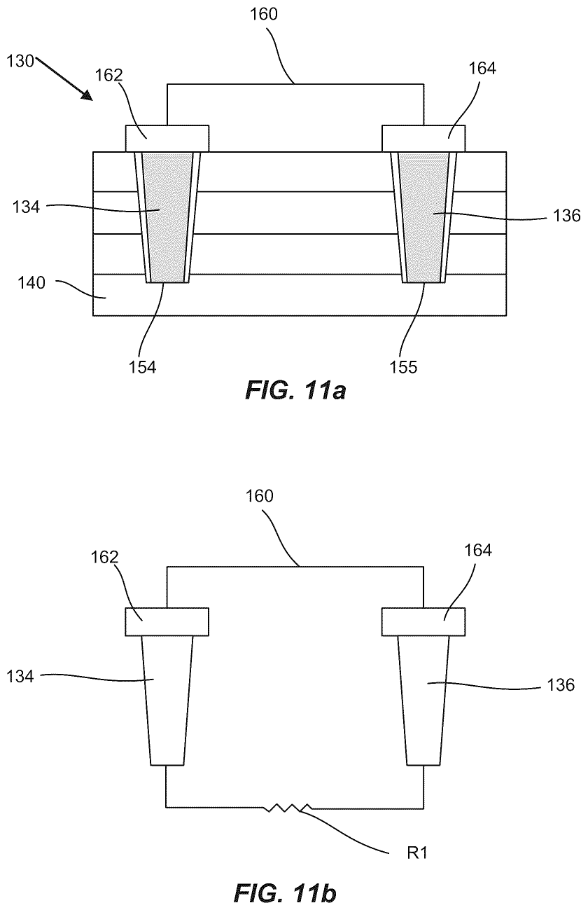

A configuration in which the TSVs (whether circuit TSVs or test TSVs) are formed to a sufficient depth is shown in FIG. 11a. As shown, test TSVs 134 and 136 are formed to a depth to reach the conductive layer 140, and with the bottom of the insulating liner etched out, conductive ends 154 and 156 of the electrically conductive material of the TSVs 134 and 136 contact the conductive layer 140. Therefore, with an electrical test meter 160 (e.g., an ohmmeter or other electrical device for measuring the presence or identifying an absence of an electrical property, such as an electrical conductance or a related property thereof (e.g., at least one of an electrical resistance, a voltage differential, another electrical property, or a combination of these capable of indicating the integrity of the TSVs) the test TSVs 134, 136 can be interrogated by contacting and applying a voltage difference to the test TSVs 134, 136. In one example, the interrogation of the first and second test TSVs 134, 136 can be performed using test probes 162 and 164, respectively, wherein a measurement of an electrical property, such as an electrical resistance or conductance can be measured between the test TSVs 134, 136 as electrical current travels between the test TSVs 134. Therefore, the configuration of FIG. 11a can be modeled as a closed electrical circuit (shown in FIG. 11B) where an electrical property, such as an electrical resistance R1 (or an electrical conductance), is measured between the test TSVs 134, 136. The interrogation via electrical probing of the test TSVs 134, 136 and the presence of electrical conductance (e.g., within a certain desired predetermined value range) can function to indicate that the test TSVs 134, 136 are formed to a correct depth, wherein the test TSVs 134, 136 can witness that the circuit TSVs 132 are formed to a correct depth and are, therefore, presumed or deduced (i.e., established) to likely be operable.

Alternatively, if an electrical property, such as an electrical resistance or conductance, cannot be measured between the first test TSV 134 and the second test TSV 136 through the conductive layer 140 (or is measured to be outside of a certain desired predetermined value range), then it can be concluded that the test TSVs 134, 136 are not formed to a sufficient depth within the substrate 110. With the test TSVs 134, 136 not being formed to a sufficient depth within the substrate 110, it is likely that the circuit TSVs 132 are also not formed to a sufficient depth, and it can be presumed or deduced (i.e., established) that these are inoperable.

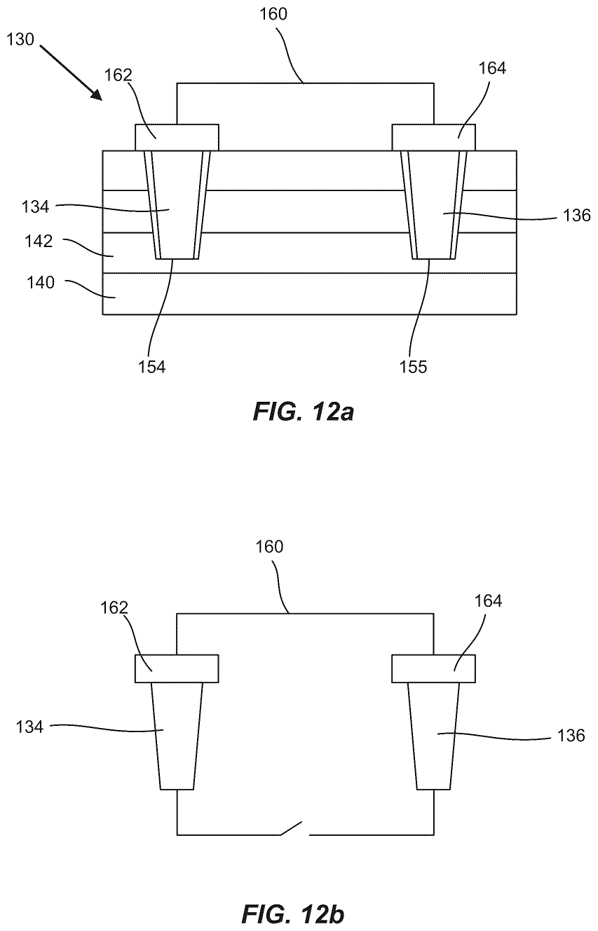

A configuration in which the TSVs (whether circuit TSVs or test TSVs) are not formed to a sufficient depth is shown in FIG. 12a. As shown, test TSVs 134, 136 are formed to a depth that only reaches an insulating layer 142 disposed on the conductive layer 140. Even with the bottom of the insulating liner etched out, conductive ends 154, 156 of the electrically conductive material of the test TSVs 134, 136 do not contact the conductive layer 140, but instead only contact the insulating layer 142. Therefore, with an electrical test meter 160 (e.g., an ohmmeter or other electrical device for measuring an electrical property, such as an electrical resistance or conductance indicating the integrity of the TSVs) contacting and applying a voltage difference to the test TSVs 134, 136 with test probes 162, 164, a measurement of an electrical resistance or a related property thereof (e.g., electrical conductance) will not be measured between the test TSVs 134, 136. As such, the configuration of FIG. 12a can be modeled as an open electrical circuit (shown in FIG. 12B) where the electrical property (e.g., electrical resistance) cannot be measured between the test TSVs 134, 136. Thereby, the interrogation (via electrical probing) of the test TSVs 134, 136 indicate that the test TSVs 134, 136 are not formed to a correct depth, wherein the test TSVs 134, 136 witness that the circuit TSVs 132 are not formed to a correct depth and thus, a deduction can be made that the circuit TSVs 132 are inoperable.

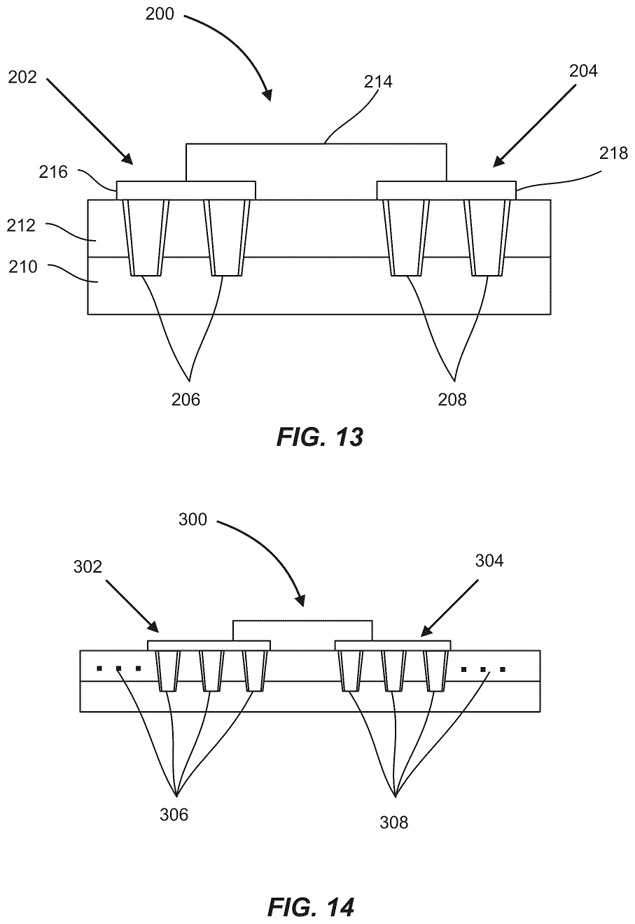

The exemplary configurations described above test the presence of, test the level of, or allow for the identifying of an absence of an electrical property between a single first test TSV 134 and a single second test TSV 136. However, other configurations are possible. For example, a first array of test TSVs comprising the first test TSV can be formed and tested in conjunction with a second array of test TSVs comprising the second test TSV. FIG. 13 illustrates an example configuration of a test structure 200 comprising a first array 202 of test TSVs 206 and a second array 204 of test TSVs 208. As illustrated, the test TSVs 206 and 208 can be formed through a substrate including a first layer 210 that can be a conductive layer 210 and a second layer 212 that can be an insulating layer 212. The TSVs 206 and 208 can be formed as in any of the examples described herein. As shown, the first array 202 and the second array 204 can be interrogated using an electrical test meter 214 or other type of interrogating device. Using the example electrical test meter 214, a first probe 216 is used to contact the first array 202 and a second probe 218 is used to contact the second array 204. Similar to the other examples described herein, the probes 216, 218 can impart voltage onto the first and second arrays 202 and 204 to determine if an electrical property (e.g., an electrical resistance or related property thereof (e.g., electrical conductance, or others)) is present and at a desired level, which will indicate that the test TSVs 206 and 208 are formed to a sufficient depth to contact the conductive layer 210, thereby permitting the test TSVs 206, 208 to function as witness TSVs to witness the operability of one or more circuit TSVs.

The number of TSVs present in an array is not intended to be limited by this disclosure and can be any desired number. FIG. 14 illustrates an example test structure 300 where a first array 302 and a second array 304 can each include any number of test TSVs 306 and 308. The first and second arrays 302, 304 of test TSVs can be formed in one or more dicing streets of a wafer. The arrays can span multiple dicing streets, can be located at an intersection of two or more dicing streets, can be confined to a single dicing street, or any combination of these. The configuration of the test structures of this disclosure in the dicing streets is not intended to be particularly limited.

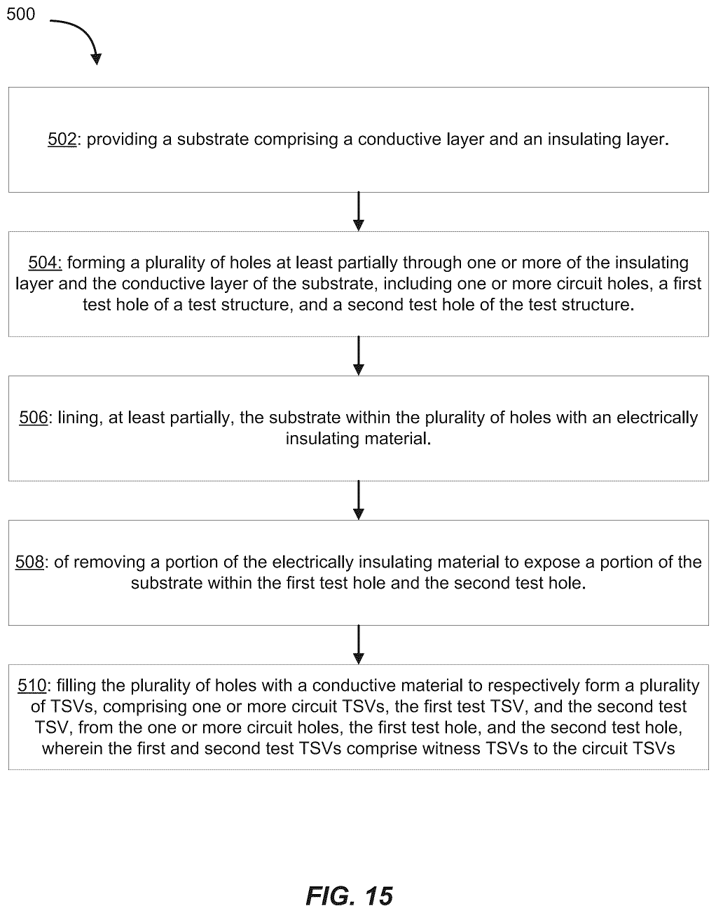

A method for configuring and testing the integrity of an integrated circuit (IC) wafer is described with reference to FIG. 15. The method 500 of configuring the wafer can include a step 502 of providing a substrate comprising a conductive layer and an insulating layer. The method 500 can further include a step 504 of forming a plurality of holes to meet one of the following descriptions: (1) forming the plurality of holes partially through the insulating layer, or (2) forming the plurality of holes through the insulating layer and partially through the conductive layer of the substrate. The plurality of holes formed according to step 504 can include one or more circuit holes associated with an integrated circuit (IC), a first test hole of a test structure, the test structure being configured to facilitate testing of the integrity of one or more circuit TSVs formed using the one or more circuit holes, and a second test hole of the test structure. The method 500 can further include a step 506 of lining, at least partially, the substrate within the plurality of holes with an electrically insulating material. The method 500 can further include a step 508 of removing a portion of the electrically insulating material to expose a portion of the substrate within the first test hole and the second test hole. The method 500 can further include a step 510 of filling the plurality of holes with a conductive material to respectively form a plurality of TSVs, comprising one or more circuit TSVs, a first test TSV, and a second test TSV, from the one or more circuit holes, the first test hole, and the second test hole, respectively, wherein the first and second test TSVs are operable to be interrogated and to function as witness TSVs to the circuit TSVs.

A method of testing integrity of TSVs in the wafer configured in method 500 can include further steps of interrogating the first and second test TSVs, such as by electrically connecting the first test TSV to the second test TSV using an electrical probe. The method and the interrogating can further include measuring the presence or identifying the absence of an electrical property (e.g., an electrical resistance or a related property thereof (at least one of electrical conductance, or another property)) between the first test TSV and the second test TSV through the conductive layer to determine the integrity of the first and second test TSVs, and to witness the integrity of the circuit TSVs. The method can further include establishing that the circuit TSVs are inoperable when missing, reduced, or diminished (i.e., outside of a desired predetermined value range) electrical resistance or related property (e.g., electrical conductance) is measured between the first and second test TSVs, and/or establishing that the circuit TSVs are operable when an electrical resistance or related property is measured between the first and second test TSVs at or within a desired predetermined value level or range.

Reference was made to the examples illustrated in the drawings and specific language was used herein to describe the same. It will nevertheless be understood that no limitation of the scope of the technology is thereby intended. Alterations and further modifications of the features illustrated herein and additional applications of the examples as illustrated herein are to be considered within the scope of the description.

Although the disclosure may not expressly disclose that some embodiments or features described herein can be combined with other embodiments or features described herein, this disclosure should be read to describe any such combinations that would be practicable by one of ordinary skill in the art. The use of “or” in this disclosure should be understood to mean non-exclusive or, i.e., “and/or,” unless otherwise indicated herein.

Furthermore, the described features, structures, or characteristics can be combined in any suitable manner in one or more examples. In the preceding description, numerous specific details were provided, such as examples of various configurations to provide a thorough understanding of examples of the described technology. It will be recognized, however, that the technology can be practiced without one or more of the specific details, or with other methods, components, devices, etc. In other instances, well-known structures or operations are not shown or described in detail to avoid obscuring aspects of the technology.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements can be devised without departing from the spirit and scope of the described technology.

What is claimed is:

1. A test structure configured to facilitate testing of the integrity of one or more circuit TSVs associated with an integrated circuit (IC), the circuit TSVs being formed at least partially through a substrate comprising an insulating layer adjacent a conductive layer, the test structure device comprising:
a first test TSV formed one of partially through the insulating layer, or through the insulating layer and partially through the conductive layer of the substrate;
a second test TSV formed one of partially through the insulating layer, or through the insulating layer and partially through the conductive layer of the substrate,
wherein the first test TSV and the second test TSV comprise witness TSVs to the circuit TSVs.

2. The test structure of claim 1, wherein the first test TSV and the second test TSV are at least partially insulated from one or more layers of the substrate.

3. The test structure of claim 2, wherein the first test TSV and the second test TSV are at least partially lined with a lining comprising an electrically insulating material to at least partially insulate the first test TSV and the second test TSV from one or more layers of the substrate; and
wherein the lining is at least partially open at a portion of the first and second TSVs.

4. The test structure of claim 1, further comprising a first array of test TSVs comprising the first test TSV.

5. The test structure of claim 1, further comprising a second array of test TSVs comprising the second test TSV.

6. The test structure of claim 1, wherein the test structure is formed as part of a circuit wafer comprising a substrate, a plurality of ICs, and one or more dicing streets, the circuit wafer being configured to be separated into dies, each die comprising an IC, and
wherein, the test structure is disposed in at least one of the dicing streets of the circuit wafer.

7. The test structure of claim 1, wherein the first test TSV and the second test TSV are configured to be connected by a test probe during testing of the integrity of the first and second TSVs,
wherein the circuit TSVs are established to be inoperable when an electrical property measured between the first and second test TSVs is outside of a predetermined value range; and
wherein the circuit TSVs are established to be operable when the electrical property measured between the first and second test TSVs is within the predetermined value range.

8. An integrated circuit wafer comprising:
a substrate comprising a conductive layer and an insulating layer;
one or more circuit TSVs formed at least partially through the substrate and associated with an integrated circuit (IC); and
a test structure configured to facilitate testing of the integrity of the one or more circuit TSVs, the test structure comprising:
a first test TSV formed one of partially through the insulating layer, or through the insulating layer and partially through the conductive layer of the substrate; and
a second test TSV formed one of partially through the insulating layer, or through the insulating layer and partially through the conductive layer of the substrate,
wherein the first test TSV and the second test TSV comprise witness TSVs to the one or more circuit TSVs.

9. The integrated circuit wafer of claim 8, wherein the first test TSV and the second test TSV are at least partially insulated from one or more layers of the substrate.

10. The integrated circuit wafer of claim 9, wherein the first test TSV and the second test TSV are at least partially lined with a lining comprising an electrically insulating material to at least partially insulate the first test TSV and the second test TSV from one or more layers of the substrate; and
wherein the lining is at least partially open at a portion of the one or more first and second TSVs.

11. The integrated circuit wafer of claim 8, wherein the one or more circuit TSVs are electrically insulated from one or more layers of the substrate.

12. The integrated circuit wafer of claim 8, wherein the one or more circuit TSVs is at least partially lined with an electrically insulating material to insulate the one or more circuit TSVs from one or more layers of the substrate.

13. The integrated circuit wafer of claim 8, further comprising a first array of test TSVs comprising the first test TSV.

14. The integrated circuit wafer of claim 8, further comprising a second array of test TSVs comprising the second test TSV.

15. The integrated circuit wafer of claim 8, further comprising:
a plurality of ICs formed thereon; and
one or more dicing streets;
wherein the integrated circuit wafer is configured to be separated into dies, each die comprising an IC; and
wherein, the test structure is disposed in at least one of the dicing streets of the circuit wafer.

16. The integrated circuit wafer of claim 8, wherein the first test TSV and the second test TSV are configured to be connected by a test probe during testing of the integrity of the one or more first and second TSVs,
wherein the circuit TSVs are established to be inoperable when an electrical property measured between the first and second test TSVs is outside of a predetermined value range; and
wherein the circuit TSVs are established to be operable when the electrical property measured between the first and second test TSVs is within the predetermined value range.

17. A method of configuring an integrated circuit wafer, the method comprising:
providing a substrate comprising a conductive layer and an insulating layer;
forming a plurality of holes one of partially through the insulating layer, or through the insulating layer and partially through the conductive layer of the substrate, the plurality of holes at least comprising:
one or more circuit holes associated with an integrated circuit (IC);
a first test hole of a test structure, the test structure being
configured to facilitate testing of the integrity of one or more circuit TSVs formed using the one or more circuit holes; and
a second test hole of the test structure,
lining, at least partially, the substrate within the plurality of holes with an electrically insulating material; and
removing a portion of the electrically insulating material to expose a portion of the substrate within the first test hole and the second test hole; and
filling the plurality of holes with a conductive material to respectively form a plurality of TSVs, comprising one or more circuit TSVs, the first test TSV, and the second test TSV, from the one or more circuit holes, the first test hole, and the second test hole, respectively, wherein the first and second test TSVs comprise witness TSVs to the circuit TSVs.

18. The method of claim 17, further comprising interrogating the first and second test TSVs, wherein the interrogating comprises:
electrically connecting the first test TSV to the second test TSV using an electrical probe;
measuring a level of an electrical property between the first test TSV and the second test TSV through the conductive layer to determine the integrity of the first and second test TSVs, and to witness the integrity of the circuit TSVs.

19. The method of claim 18 further comprising:
establishing that the circuit TSVs are inoperable when the electrical property measured between the first and second test TSVs is outside of a predetermined value range; and
establishing that the circuit TSVs are operable when the electrical property measured between the first and second test TSVs is within the predetermined value range.
